(19) United States
(12) Patent Application Publication
(10) Pub. No.: US 2018/0358258 A1
(43) Pub. Date: Dec. 13, 2018

(54) SINGLE MASK LEVEL FORMING BOTH TOP-SIDE-CONTACT AND ISOLATION TRENCHES

(71) Applicant: Texas Instruments Incorporated, Dallas, TX (US)

(72) Inventors: ZACHARY K. LEE, FREMONT, CA (US); ROBERT GRAHAM SHAW, NASHUA, NH (US); HIDEAKI KAWAHARA, PLANO, TX (US); ASAD MAHMOOD HAIDER, PLANO, TX (US); YUJI MIZUGUCHI, FUKSHIMA (JP); HIROSHI YAMASAKI, FUKUSHIMA (JP); ABBAS ALI, PLANO, TX (US); BRIAN GOODLIN, PLANO, TX (US)

(21) Appl. No.: 15/618,642

(22) Filed: Jun. 9, 2017

(51) Int. Cl. H01L 21/74; H01L 27/12; H01L 29/06; H01L 29/78; H01L 29/10; H01L 21/84

(52) U.S. Cl. CPC H01L 21/743; H01L 27/1203; H01L 21/84; H01L 29/7816; H01L 29/1087; H01L 29/0649

(57) ABSTRACT

A method of forming an integrated circuit includes forming ≥1 hard mask layer on a device layer on a BOX layer of a SOI substrate. A patterned masking layer is used for a trench etch to simultaneously form larger and smaller area trenches through the hard mask layer, device layer and the BOX layer. A dielectric liner is formed for lining the larger and smaller area trenches. A dielectric layer is deposited for completely filling the smaller area trenches and only partially filling the larger area trenches. The larger area trenches are bottom etched through the dielectric layer to provide a top side contact to the handle portion. The handle portion at a bottom of the larger area trenches is implanted to form a handle contact, and the larger area trenches are completely filled with an electrically conductive layer to form a top side ohmic contact to the handle contact.

### FIELD

Disclosed embodiments relate to semiconductor device fabrication and more specifically to Silicon-on-Insulator (SOI) processing for forming integrated circuits that include top-side-contact trenches for connection to the handle portion through the top-side of the chip and isolation trenches for electrical isolation between components on the chip.

### BACKGROUND

SOI is a semiconductor technology that produces higher performing, lower power (dynamic) devices as compared to traditional bulk silicon-based technology. SOI substrates are used for a variety of applications including Micro-Electro-Mechanical Systems (MEMS), power devices, and complementary metal-oxide-semiconductor (CMOS) integrated circuits (ICs). The SOI wafer comprises a sandwich structure including a device layer (or active layer) on the top, a buried oxide (BOX) layer (dielectric typically being silicon oxide) in the middle, and a handle portion or ‘handle wafer’ (typically being bulk silicon) on the bottom. SOI wafers can be produced by using a SIMOX (Separation by IMplantation of Oxygen) process which uses a very high dose oxygen implant process followed by a high temperature anneal, or wafer bonding to achieve thinner and precise device layer and ensure the requirement of thickness uniformity and low defect density.

In high voltage SOI processes, the handle portion potential with respect to the circuit components in the device layer can have a profound effect on the performance and electrical characteristics of these components. For example, the breakdown voltage, drive current, safe operating area (SOA), and capacitance of a drain extended MOS transistor such as a laterally diffused MOSFET (LDMOS) transistor are typically functions of the handle portion potential. It is therefore generally important to have a well-defined potential in the handle portion in order to ensure proper IC functionality.

The handle portion is commonly tied to certain fixed potentials with respect to the device layer (e.g., lowest potential or ground) through the IC packaging. This can be inconvenient and in some situations it can be difficult to implement, especially in situations where the handle portion needs to be tied to some high voltage. In these cases a top-side-contact (TSC) trench that allows connection to the handle portion through the top-side of the die is therefore useful.

### SUMMARY

This Summary is provided to introduce a brief selection of disclosed concepts in a simplified form that are further described below in the Detailed Description including the drawings provided. This Summary is not intended to limit the claimed subject matter's scope.

Disclosed embodiments include SOI process flows that form both smaller area trenches (e.g., isolation trenches) and larger area trenches (TSC trenches) using a single masking step, which by reducing one masking level provides a significant IC cost reduction. A method of forming an IC comprises forming at least one hard mask layer on a device layer of a SOI substrate including the device layer on a top, BOX layer in a middle, and a handle portion on a bottom. A pattern is etched using masking comprising a patterned masking layer to simultaneously to form both larger area trenches and smaller area trenches etching through the hard mask layer, the device layer, and the BOX layer. A dielectric liner is formed for lining the larger area trenches and for lining the smaller area trenches. A deposited dielectric layer fills the smaller area trenches but only partially fills a portion of the larger area trenches.

The larger area trenches are bottom etched through the deposited dielectric layer to provide a top side contact to the handle portion. The handle portion is implanted at a bottom of the larger area trenches to form a handle contact, and the larger area trenches are filled with an electrically conductive layer (e.g., doped polysilicon) to form a top side ohmic contact to the handle contact.

### BRIEF DESCRIPTION OF THE DRAWINGS

Reference will now be made to the accompanying drawings, which are not necessarily drawn to scale, wherein:

FIGS. 1A-1J are schematic cross-sectional diagrams showing process progression for an example single mask level method for forming both TSC and isolation trenches, according to an example embodiment.

FIG. 2 is a cross sectional view of a portion of an IC having transistors in the device areas that are isolated from one another by isolation trenches, where the IC also has TSC trenches for top side handle portion contact, according to an example embodiment.

FIG. 3A is a top view of a portion of an IC having a high voltage device within an inner isolation ring, where an outer TSC trench shown as a TSC ring also surrounds the high voltage device. FIG. 3B shows a double isolation ring so that the device layer in between the isolation rings shown as a shielding island is provided.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

Also, the terms “coupled to” or “couples with” (and the like) as used herein without further qualification are intended to describe either an indirect or direct electrical connection. Thus, if a first device “couples” to a second device, that connection can be through a direct electrical connection where there are only parasitics in the pathway, or through an indirect electrical connection via intervening items including other devices and connections. For indirect coupling, the intervening item generally does not modify the information of a signal but may adjust its current level, voltage level, and/or power level.

As noted above, disclosed embodiments include methods of forming SOI ICs including larger area trenches (e.g., TSC trenches) and smaller area trenches (e.g., isolation trenches) using single mask level method of forming both of these trench sizes. The single mask level can form both high aspect ratio (AR) isolation trenches (e.g., 3 to 15) and lower AR wider TSC trenches that ohmically contact the handle portion of the SOI IC die from the top side of the die so that the IC can be biased at a desired voltage without the need for a down bond.

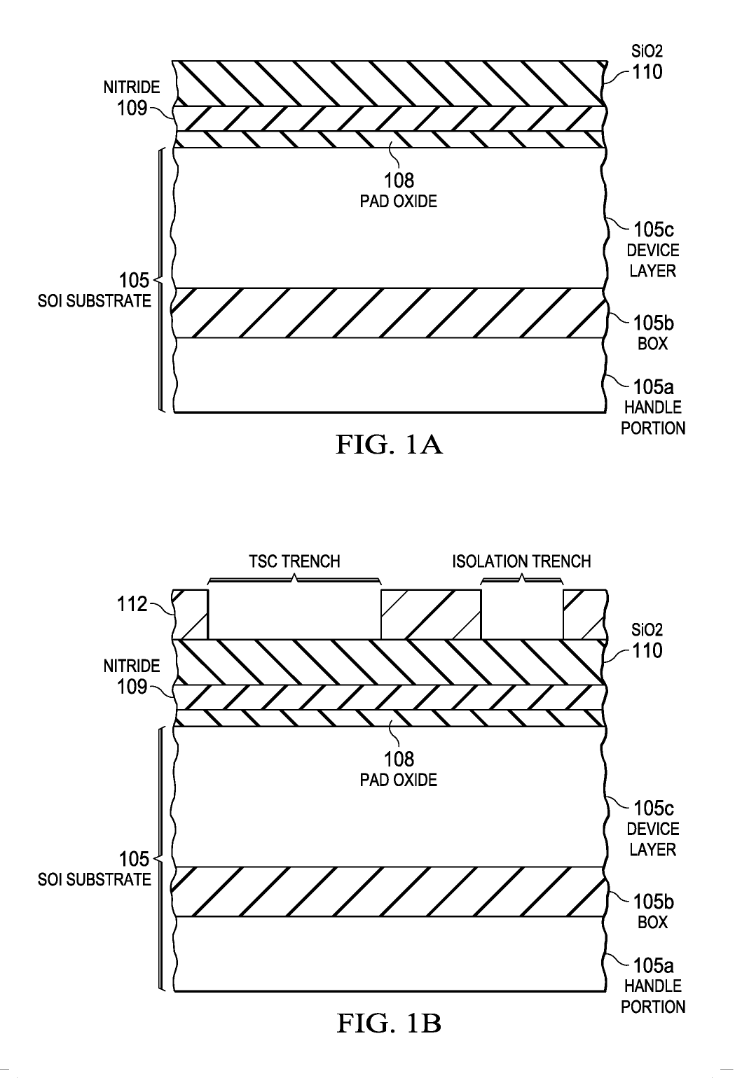

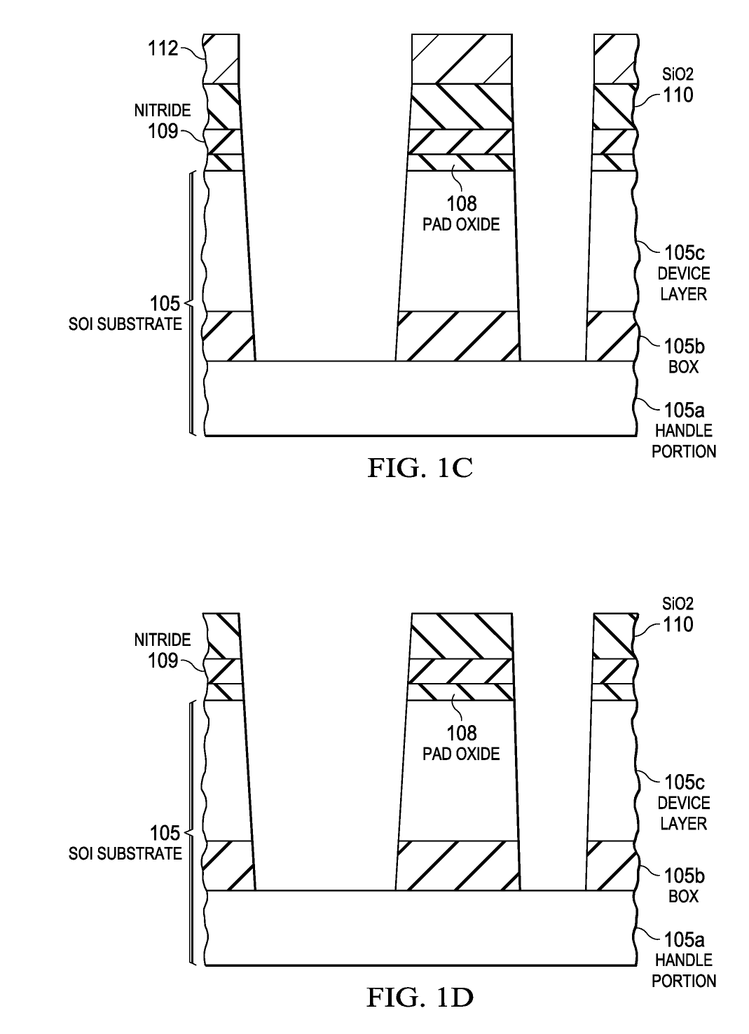

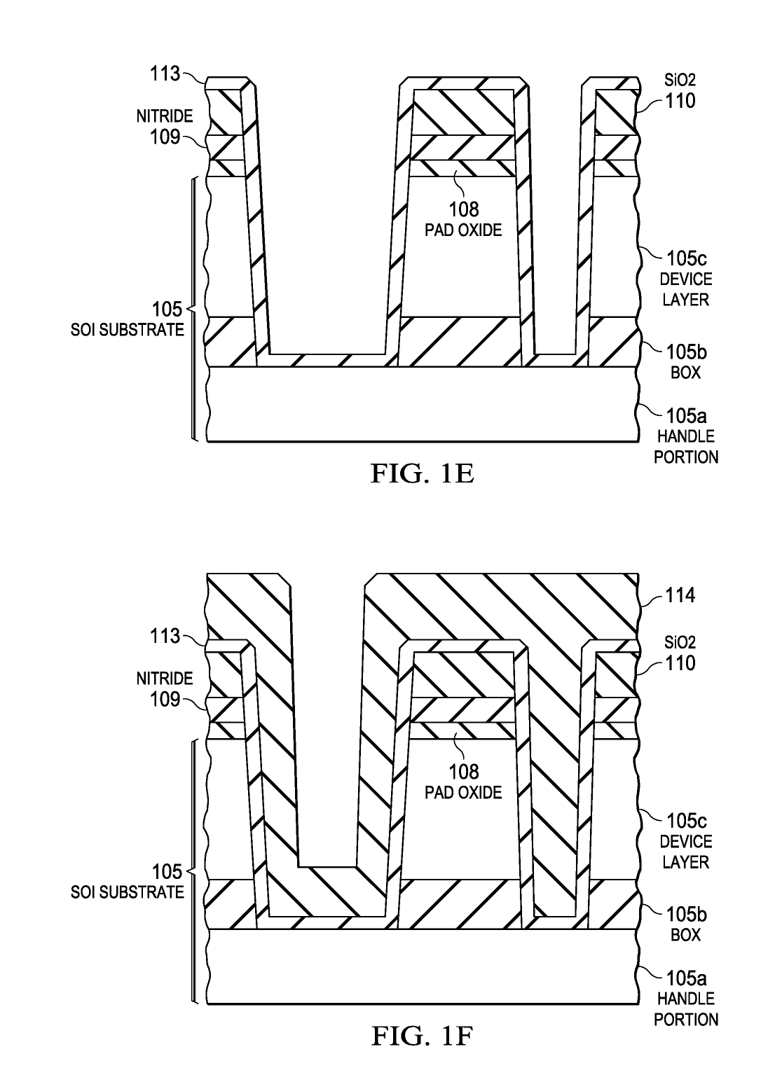

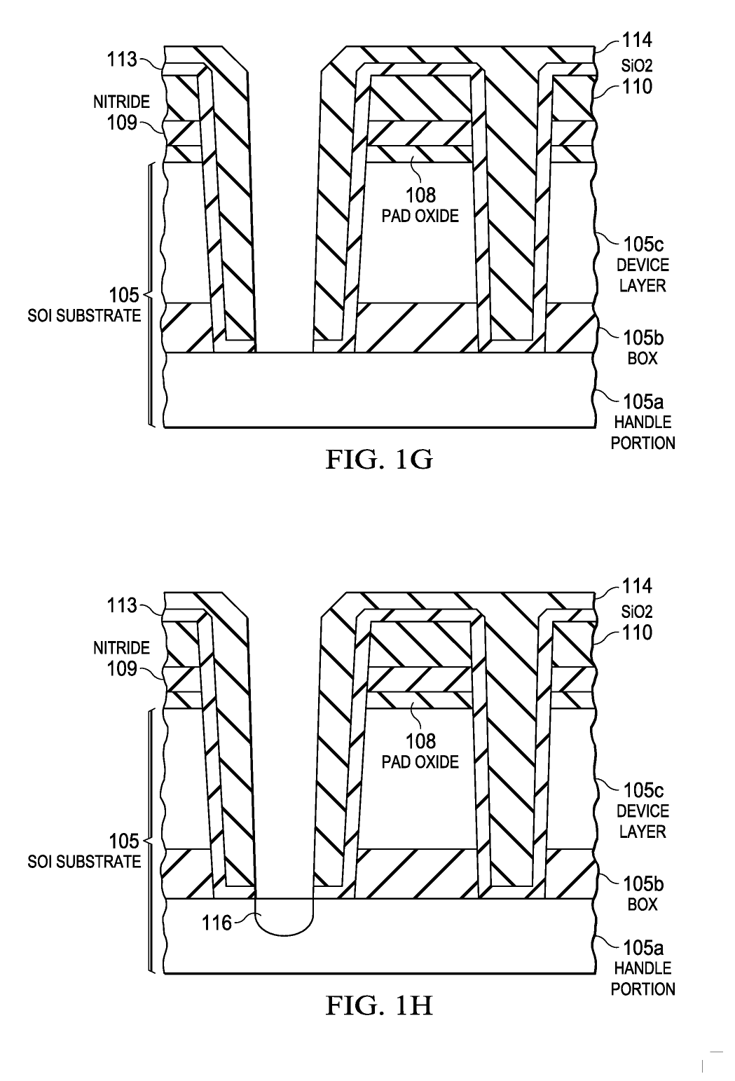

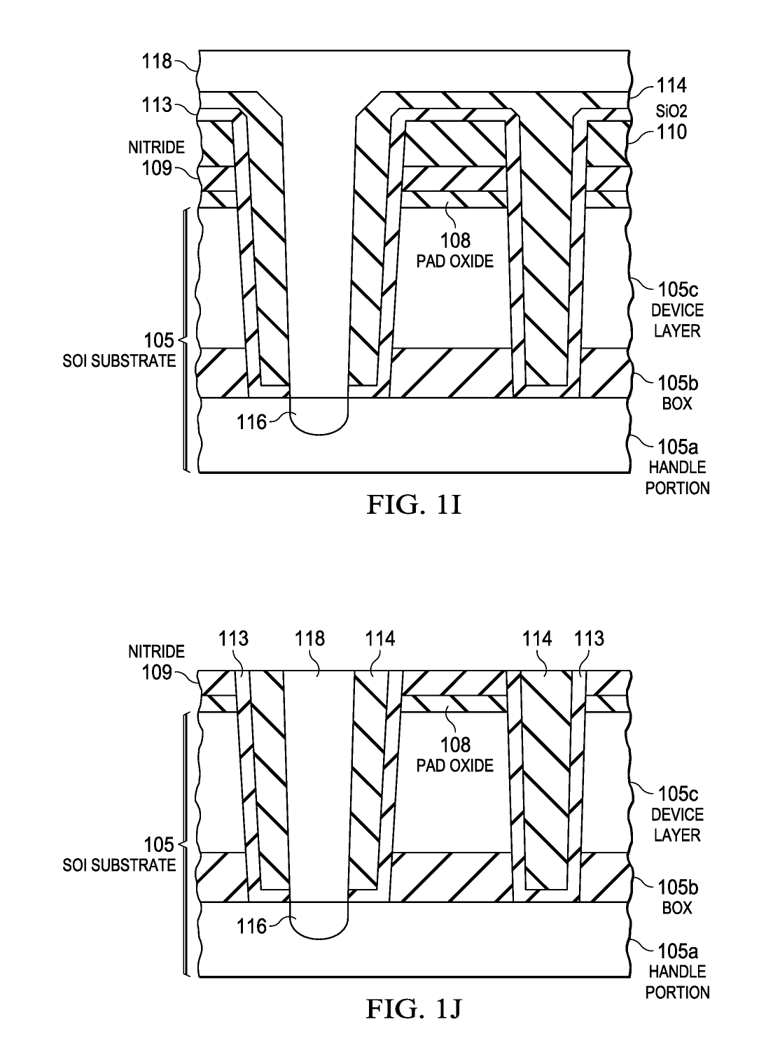

FIGS. 1A-1J are schematic cross-sectional diagrams showing process progression for an example method of forming an SOI IC using a single mask level for forming both larger area trenches shown as the TSCs and smaller area trenches shown as isolation trenches. FIG. 1A shows a portion of the in-process IC after the depositing of at least one hard mask layer on a device layer 105c (or ‘active layer’) of a SOI substrate 105. The SOI substrate 105 includes the device layer 105c on the top, a BOX layer 105b in the middle, and a handle portion 105a on the bottom. The hard mask layer is shown by example as a three-layer hard mask stack including a top deposited silicon oxide layer 110, a deposited silicon nitride layer 109 in the middle, and thermal silicon ‘pad’ oxide layer 108 on the bottom.

In a typical embodiment the device layer 105c comprises silicon, the BOX layer 105b comprises silicon oxide, and the handle portion 105a comprises silicon. The device layer 105c can comprise a lower portion comprising single crystal silicon from the SOI substrate from an SOI wafer vendor and an upper portion comprising an epitaxial silicon layer. The device layer 105c can be from 1 μm to 10 μm thick, such as 3 μm to 6 μm thick, the BOX layer 105b can be from 1 μm to 4 μm thick, and the handle portion 105a can be from 100 μm to 1,000 μm (1 mm) thick. In one particular embodiment the top deposited silicon oxide layer 110 is Plasma enhanced chemical vapor deposition (PECVD) deposited and is 1 μm to 2 μm thick, the deposited silicon nitride layer 109 is LPVCD (or PECVD) deposited and is 0.1 μm to 0.4 thick, and the pad oxide 108 is 100 A to 300 A thick and is thermally grown.

FIG. 1B shows a portion of the in-process IC after forming a pattern to define both larger area trenches shown as over an area that will be a TSC trench which will contact a top surface of the handle portion 105a and smaller area trenches shown as an isolation trench which extend into the BOX layer 105b. The forming of the pattern can comprise photoresist coating, patterning and developing to provide the patterned masking layer 112 shown. The patterned masking layer 112 (e.g., photoresist) generally should be thick enough so that there is still some masking layer left over after etching to form the trenches.

FIG. 1C shows a portion of the in-process IC after deep trench etching to simultaneously form trenches both the larger area TSC trenches and the smaller area isolation trenches. The trench etching can comprise deep reactive ion etching (DRIE) which anisotropically etches through the hard mask layers 110, 109, 108, the device layer 105c and BOX layer 105b to enable biasing the handle portion 105a from the top side of the IC during operation of the IC. The trench depth can range from 2 μm to 15 μm. The trench width for the isolation trenches can be from 0.4 μm to 1.9 μm, and the trench width for the TSC trenches can be at least 1.5 or 2 times the isolation trench width up to about 4 times the isolation trench width, such as in the range from 2 μm to 7 μm.

FIG. 1D shows a portion of the in-process IC after removal of the masking layer 112. For example, the masking layer 112 removal can comprise ashing and then cleaning in the case the masking layer 112 comprises photoresist.

FIG. 1E shows a portion of the in-process IC after forming a dielectric liner 113 for lining the larger area TSC trenches and for lining the smaller area isolation trenches. The dielectric liner 113 can comprise a deposited High Temperature Oxide (HTO) liner using a LPCVD process at temperature of 500° C. or higher, or a thermally grown oxide. The dielectric liner 113 is generally 100 A to 500 A thick.

FIG. 1F shows a portion of the in-process IC after depositing a dielectric layer 114 shown partially filling the larger area TSC trenches and completely filling the smaller area isolation trenches. The dielectric layer 114 can comprise a sub-atmospheric chemical vapor deposition (SACVD) deposited layer, such as SACVD silicon oxide or silicon oxynitride. The dielectric layer 114 can also comprise other dielectric materials that provide a high breakdown voltage barrier for the isolation trench, be a low stress layer so it does not have a tendency to crack, have low shrinkage when thermally cycled, provide good fill capability, and generally be relatively low cost.

A typical deposition pressure used for the SACVD deposition is from 300 torr to 700 torr. For depositing a SACVD silicon oxide the reagents can comprise Tetraethyl orthosilicate (TEOS) and O₃ (ozone) in a temperature range from 500° C. to 560° C., with the deposited thickness range depending on the trench volume for the smaller area isolation trenches being filled, such as 0.9 μm to 4 μm thick in one embodiment. SACVD is capable of completely filling high AR trenches, such as isolation trenches having an AR from 3 to 15.

FIG. 1G shows a portion of the in-process IC after bottom etching of the larger area TSC trenches through the dielectric layer 114 to provide a TSC opening extending into the handle portion 105a. In the cases the dielectric layer 114 comprises a silicon oxide layer, this etch generally comprises a dry etch. Since the dielectric layer 114 in the wider TSC trench is thinner at the bottom compared to the width of the isolation trench, the dielectric layer 114 at the bottom of the TSC trench is completely cleared. Since the narrower isolation trench is overfilled with the dielectric layer 114 oxide, this etch as shown does not affect the dielectric layer 114 fill inside the isolation trench. In the case the dielectric layer 114 comprises a SACVD dielectric layer a densification step is generally added to remove as-deposited voids, such as a 950° C. to 1050° C. densification for 20 to 40 minutes in a non-oxidizing ambient such as a N₂ ambient. The SACVD dielectric layer densification step can be performed before (on the as-deposited, undensified dielectric) or after it is etched.

There is generally no masking layer used for this bottom etching so that the SACVD dielectric layer 114 is blanket etched resulting in the field regions of the SACVD dielectric layer 114 being thinned too as shown in FIG. 1G. The blanket etch process can comprise a plasma etch process using C₄F₈/Ar/O₂ chemistry at about 40 mTorr and 1,700 W of radio frequency (RF) power. For disclosed methods using a SACVD oxide the thickness of the dielectric layer 114 decreases during both this bottom etching process as well as the subsequent thermal densification step, and more of a thickness decrease generally results from the bottom etching in the case of a plasma etch compared to thermal densification.

The dielectric layer 114 thickness range in the case of a SACVD dielectric after densifying and blanket bottom etching for an as-deposited SACVD dielectric layer thickness of 0.9 μm to 1.1 μm is less than 0.45 μm (=4.5 kA) on the field, thus providing more than a 50% total thickness reduction. The densification process generally results in 4% to 10% film shrinkage, while the bulk of the SACVD thickness decrease generally results from the earlier bottom etch process.

FIG. 1H shows a portion of the in-process IC after ion implanting bottom of the larger area trenches TSC trenches (TSC bottom implanting) including implanting into the handle portion 105a to form a handle portion contact 116. The ion implanting comprises a p-type implant for a p-type handle portion, and an n-type implant for an n-type handle portion. For example, for a p-type handle portion boron may be used with a dose from 1×10¹⁴ to 9×10¹⁵ cm⁻², an energy from 20 keV to 40 keV, a 0 degree tilt and a 45 degree twist angle. This ion implant is generally a blanket implant. The blanket implant is thus implanted into the entire surface of dielectric layer 114, but later in the process the dielectric layer 114 on the field regions of the IC is removed generally by a Chemical Mechanical Planarization (CMP) process as described below.

FIG. 1I shows a portion of the in-process IC after filling the TSC trenches with a doped polysilicon layer 118 to form a top side ohmic contact to the handle portion contact 116 with the doped polysilicon layer 118 shown extending lateral to the TSC trench as overburden portions. Since the isolation trench is already filled with the dielectric layer 114, the doped polysilicon layer 118 will not go into the isolation trench. The doped polysilicon layer 118 comprises a p-doped layer for a p-type handle portion and an n-doped layer for an n-type handle portion. For a p-type handle portion an in-situ doped polysilicon deposition can comprise LPCVD utilizing silane (SiH₄) gas and a dopant gas such as BCl₃ at a deposition temperature range of 550° C. to 650° C. and a pressure range from 100 mTorr to 400 mTorr. The doped polysilicon layer 118 thickness may be about 1.6 μm to 2.2 μm. In-situ doped polysilicon may be used, or it can be deposited undoped then ion implanted to dope it. However, in-situ doped polysilicon may be preferred in processes where there is insufficient thermal cycling for the implanted dopants to reach deep enough into the polysilicon filled TSC which would otherwise result in high TSC resistance. After completion of fabricating the IC the polysilicon filled TSC generally has a 25° C. sheet resistance less than or equal (≤) 70 ohms/sq.

FIG. 1J shows a portion of the in-process IC after removing the overburden portions of the doped polysilicon layer 118. CMP may be used. The poly CMP process is shown stopping on the silicon nitride layer 109.

Although the process progression shown in FIGS. 1A-1J described above does not include showing the formation of a field dielectric, there is generally a field dielectric formed within and between the devices either before or after forming the TSC and isolation trenches. The field dielectric as known in the art can comprise Local Oxidation of Silicon (LOCOS) or shallow trench isolation (STI).

Although not shown, as well known in the art subsequent IC processing includes lithography, etching, thin film depositions and growth, diffusion, and ion implants for forming a desired pattern of transistors, resistors and capacitors. Metallization follows generally comprising a multi-level metallization stack, followed by forming a patterned passivation layer to expose the bond pads.

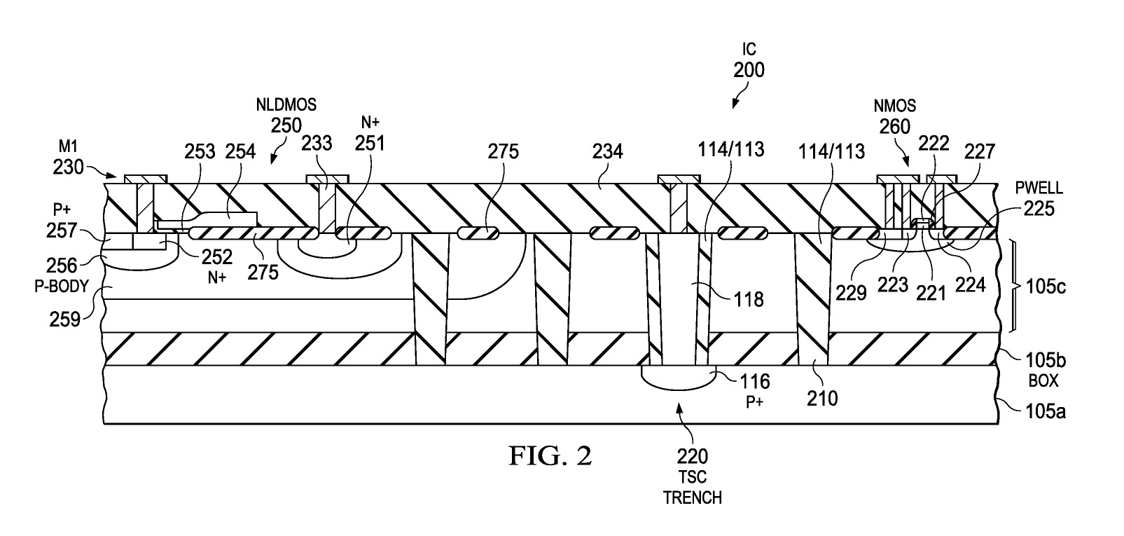

FIG. 2 is a cross sectional view of a portion of an IC 200 having transistors in the device areas that are isolated from one another by isolation trenches 210, where the IC 200 also has TSC trenches 220 for top side handle portion contact, according to an example embodiment. Because characteristics of many different kinds of circuit components are affected by handle portion bias, the TSC trenches 220 on the IC 200 provide the desirable ability to control the handle voltage bias at an appropriate bias level from the top side of the IC without the conventional need for down bonds to either ground the handle portion or maintain the handle portion 105a at any desired voltage.

For simplicity the metal stack is shown as only a patterned metal 1 (M1) layer 230 connecting through filled (e.g., tungsten (W) filled) vias 233 that are through a pre-metal dielectric layer 234 to provide contact to features in or on the top surface of the device layer 105c. Not all needed contacts are shown, such as contacts to the respective gates. Typically, the metal stack will include 4 or more metal layers with an interlevel dielectric (ILD) layer having vias therein between the respective metal layers.

The transistors shown comprise a laterally diffused n-channel metal-oxide-semiconductor (NLDMOS) transistor 250, and a conventional n-channel MOS (NMOS) transistor 260. The field oxide is shown as a LOCOS oxide 275, but as noted above can also comprise STI. As used herein, an LDMOS device is synonymous with a diffused metal oxide semiconductor (DMOS) or drain extended MOS (DEMOS) device and can include both n-channel LDMOS (NLDMOS) and p-channel PLDMOS devices. In NLDMOS transistor 250, the drain 251 is laterally arranged to allow current to laterally flow, and an n-drift region is interposed between the channel and the drain to provide a high drain 251 to source 252 breakdown voltage (BV). The source 252 is in a p-body region 256 (sometimes called a DWELL region) formed within an n-body region 259 that has a p+ contact 257. LDMOS devices are thus generally designed to achieve higher BV while minimizing specific ON-resistance in order to reduce conduction power losses. NLDMOS transistor 250 also has a gate electrode 254 such as an n+ polysilicon gate that is on a gate dielectric layer 253.

NMOS transistor 260 includes a gate electrode 221 on a gate dielectric 222 along with a drain 223 and source 224 formed in a pwell 225. Spacers 227 are shown on the sidewalls of the gate stack of the NMOS transistor 260. There is also a p+ contact 229 shown to the pwell 225. The IC 200 can also include PMOS devices by generally changing the doping types relative to NMOS devices.

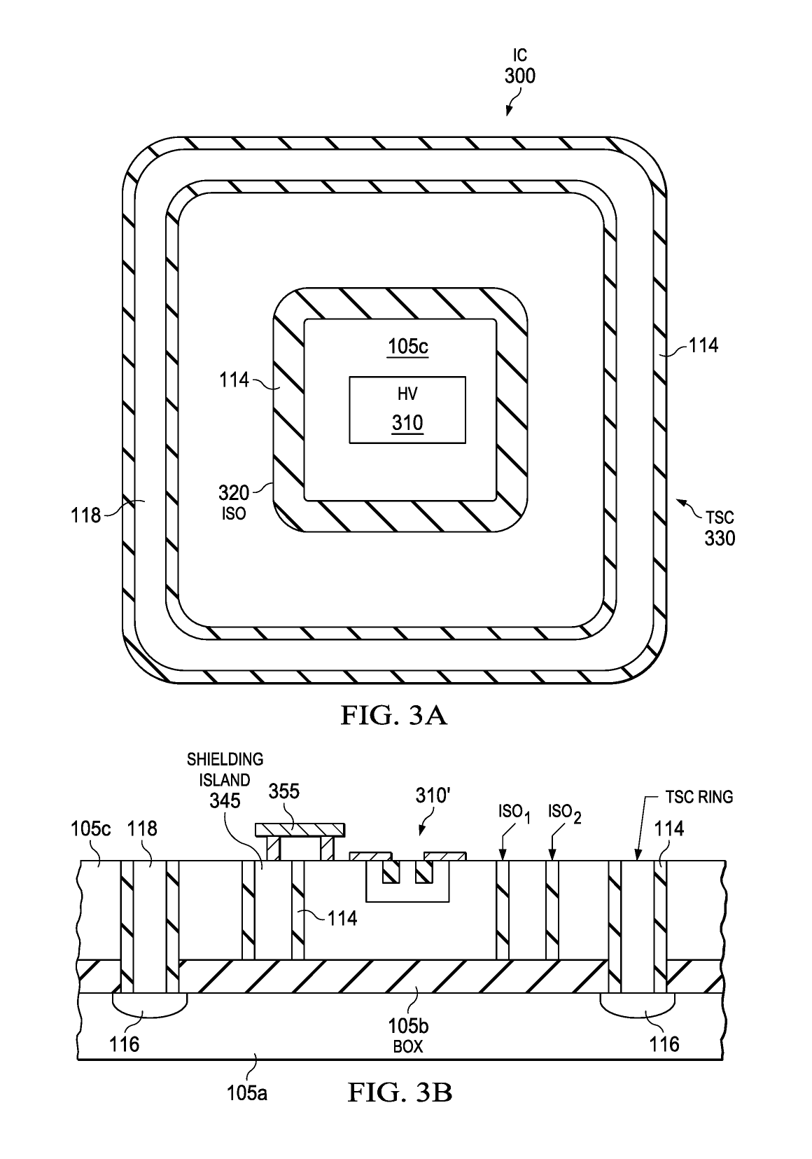

FIG. 3A is a top view of a portion of an IC 300 having a high voltage device 310 (e.g., an LDMOS device) within an inner isolation ring (shown as ‘ISO’) 320, where an outer TSC trench shown as a TSC ring 330 also surrounds the high voltage device 310. The TSC ring 330 surrounds the high voltage device 310 which has its own ISO ring 320 so that the TSC ring 330 can function to isolate the high voltage device 310 from disturbances or couplings from the device layer 105c outside of the TSC ring 330. Besides rings, the TSC trenches can be configured to not be encircling, such as being configured as one or more lines (e.g., a pair of parallel lines).

Although only one ISO ring 320 is shown in FIG. 3A, 2 or more ISO rings can be stacked in series to provide a higher voltage isolation or to improve the isolation (i.e., an ISO ring within an ISO ring within another ISO ring). As shown in FIG. 3B, for devices that are sensitive to coupling from IC regions outside, with the device shown as high voltage device 310′, a double ISO ring shown as an inner ISO ring shown as an ISO₁ ring and an outer ISO ring shown as an ISO₂ ring (or 3 or more ISO rings) can be used such that the device layer 105c that comprises a semiconductor (e.g., silicon) in between the isolation rings shown as a shielding island 345 for the device 310′ is provided between the ISO₁ ring and ISO₂ ring. A metal connection shown as 355 couples together the device layer 105c between the shielding island 345 and the island of device layer 105c where the high voltage device 310′ is formed in.

Disclosed embodiments can be used to form SOI semiconductor die that may be integrated into a variety of assembly flows to form a variety of different devices and related products. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can be formed from a variety of processes including bipolar, Insulated Gate Bipolar Transistor (IGBT), CMOS, BiCMOS and MEMS.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

1. A method of forming an integrated circuit (IC), comprising:
forming a hard mask layer on a device layer of a silicon-on-insulator (SOI) substrate including a handle portion and a buried oxide (BOX) layer between said device layer and said handle portion, said hard mask layer including a thermal silicon oxide layer directly on said device layer, a silicon nitride layer directly on said thermal silicon oxide layer, and a plasma-deposited silicon oxide layer directly on said silicon nitride layer;
etching using a patterned masking layer to simultaneously form both wider trenches and narrower trenches through apertures in said masking layer, etching through said device layer and said BOX layer;
forming a dielectric liner on sidewalls of said wider trenches and said narrower trenches;
depositing a dielectric layer such that said narrower trenches are completely filled and an opening remains within said wider trenches;
removing said dielectric layer at a bottom of said wider trenches thereby exposing said handle portion;
implanting said handle portion at bottoms of said wider trenches thereby forming handle contacts, and
completely filling said wider trenches with an electrically conductive layer thereby forming top side electrical connections to said handle portion.

2. The method of claim 1, wherein a width of said wider trenches is greater than or equal to (≥) 1.5 times a width of said narrower trenches.

3. The method of claim 1, wherein said dielectric layer comprises silicon oxide and said bottom etching comprises dry etching.

4. The method of claim 1, wherein said electrically conductive layer comprises doped polysilicon, and wherein said completely filling comprises depositing in-situ doped polysilicon.

5. The method of claim 4, further comprising removing overburden regions of said doped polysilicon by Chemical Mechanical Planarization (CMP), stopping on said hard mask layer lateral to said wider trenches and said narrower trenches.

6. The method of claim 1, wherein said handle portion is p-doped, wherein said implanting said handle portion comprises p-type implanting, and wherein said electrically conductive layer comprises p-doped polysilicon.

7. The method of claim 1, wherein said depositing said dielectric layer comprises sub-atmospheric pressure chemical vapor deposition (SACVD) thereby forming a SACVD dielectric, and further comprising densifying said SACVD dielectric before said bottom etching.

8. The method of claim 1, wherein said narrower trenches are configured as inner rings around corresponding electronic devices formed in said device layer, and wherein said wider trenches are configured as outer rings around corresponding ones of said inner rings.

9. The method of claim 1, wherein said wider trenches and said narrower trenches have a trench depth in a range from about 2 μm to about 15 μm.

10. The method of claim 1, wherein said IC includes at least one drain extended metal-oxide-semiconductor (DEMOS) transistor surrounded by one of said narrower trenches and one of said wider trenches.

11-19. (canceled)

20. A method of forming an integrated circuit (IC), comprising:
forming a hard mask layer on a device layer of a silicon-on-insulator (SOI) substrate including a handle portion and a buried oxide (BOX) layer between said device layer and said handle portion, said hard mask layer including a thermal silicon oxide layer directly on said device layer, a silicon nitride layer directly on said thermal silicon oxide layer, and a plasma-deposited silicon oxide layer directly on said silicon nitride layer;
etching using a patterned masking layer to simultaneously form both wider top-side-contact (TSC) trenches and narrower isolation trenches through apertures in said masking layer, etching through said device layer and said BOX layer;
lining said TSC trenches and said isolation trenches with a dielectric liner;
depositing a dielectric layer such that said isolation trenches are completely filled and an opening remains within said TSC trenches;
removing said dielectric liner at bottoms of said TSC trenches thereby exposing said handle portion;
implanting said handle portion at bottoms of said TSC trenches thereby forming handle contacts, and
completely filling said TSC trenches with an electrically conductive layer thereby forming top side ohmic connections to said handle portion.

21. A method of forming an integrated circuit (IC), comprising:
forming a hard mask over a semiconductor layer, said hard mask layer including a thermal silicon oxide layer directly on said semiconductor layer, a silicon nitride layer directly on said thermal silicon oxide layer, and a plasma-deposited silicon oxide layer directly on said silicon nitride layer;
forming openings within said hard mask, said semiconductor layer and a buried oxide layer over a handle portion, said forming removing at least a portion of said buried oxide layer at bottoms of said openings;
depositing a dielectric layer into said openings, wherein said dielectric layer completely fills a narrower subset of said openings and partially fills a wider subset of said openings;
removing said dielectric layer from bottoms of said wider openings, thereby exposing said handle portion at said bottoms of said wider openings;
filling said wider openings with an electrically conductive material thereby forming a conductive path to said handle portion.

22. The method of claim 21, wherein said dielectric layer is deposited by sub-atmospheric pressure chemical vapor deposition (SACVD).

23. The method of claim 21, wherein said openings comprise trenches.

24. The method of claim 21, further comprising implanting a dopant into said handle portion after said exposing, such that said electrically conductive material forms an ohmic connection to said handle portion.

25. The method of claim 21, further comprising forming a dielectric liner within said openings before depositing said dielectric layer.

26. The method of claim 21, further comprising densifying said dielectric layer before said filling.

27. The method of claim 26, wherein said densifying is done after said removing.

28. The method of claim 26, wherein said forming exposes said handle portion at said bottoms.

29. The method of claim 21, further comprising removing an overburden of said electrically conductive material, thereby exposing a hard mask over said device layer between said wider openings and said narrower openings.
